(19) United States
(12) Patent Application Publication
(10) Pub. No.: US 2018/0054164 A1
(43) Pub. Date: Feb. 22, 2018

(54) STRUCTURE OF AN INTEGRATED CRYSTAL OSCILLATOR PACKAGE

(71) Applicant: DAPA INC., TAOYUAN CITY (TW)

(72) Inventor: TING-YI CHEN, TAOYUAN CITY (TW)

(21) Appl. No.: 15/281,893

(22) Filed: Sep. 30, 2016

(30) Foreign Application Priority Data
Aug. 17, 2016 (TW) 105126285

(51) Int. Cl. H03B 5/32; H05K 1/03; H05K 1/02; H04R 3/00; H04M 1/02

(52) U.S. Cl. CPC H03B 5/32; H05K 1/0306; H05K 1/0237; H05K 2201/10083; H04M 1/026; H03B 2200/002; H04R 3/00

(57) ABSTRACT

A structure of an integrated crystal oscillator package has a first quartz crystal resonator, a second quartz crystal resonator, and application-specific integrated circuit chip (ASIC) combined in a package. The ASIC has a switch control for receiving audio formats of 44.1 kHz and 48 kHz with different hi-fidelity (hi-fi). The first quartz crystal resonator has a first clock rate corresponding to the 44.1 kHz frequency and the second quartz crystal resonator has a second clock rate corresponding to the 48 kHz frequency to be switched by the present invention in operation.

### BACKGROUND OF THE INVENTION

### 1. Field of the Invention:

The present invention relates to a structure of an integrated crystal oscillator package that has a first quartz crystal resonator, a second quartz crystal resonator, and an application-specific integrated circuit chip combined in a package.

### 2. Description of the Related Art:

Music players have been an important portion in smartphones. Some manufacturers even install an acoustic module from high-end players onto smartphones for better hi-fidelity (hi-fi) of the music. Such acoustic module has a quartz crystal resonator therein and a circuit designed to make use of the oscillation frequencies produced by piezoelectric effects to enhance the oscillation frequency of the quartz crystal resonator. Operations of such crystal oscillator package can be further divided into crystal resonator and crystal oscillator structures.

FIG. 1A discloses a structure of a conventional crystal resonator package 10 which has a substrate 11, a crystal resonator 12 mounted on the substrate 11 by silver glues 13, and a cover 14 placed on the substrate 11. Then referring to FIG. 1B, two crystal resonators 10 are separately mounted on a PCB P of a smartphone to be operated by an integrated circuit (IC) thereon—to individually output a first clock rate and a second clock rate. Such structure is able to save the costs for parts in the manufacturing process and has a fair covering area on the smartphone and a fair integration of the different clock rates. However, the structure is unable to hold control of the phase noises produced in the process.

FIG. 1C discloses another structure of a conventional crystal oscillator package 20 that has a substrate 21 with a staircase depression 211 and a stair surface 212, an application-specific integrated circuit chip (ASIC) 22 disposed on the depression 211, a crystal resonator 23 mounted on the stair surface 212 by silver glues 24, and a cover 25 covered on the substrate 21. FIG. 1D illustrates two of the crystal oscillators 20 mounted on a PCB P of a smartphone, each of which outputting a clock rate for operation.

In FIG. 1E, a structure of another crystal oscillator package 30 is illustrated, including a substrate 31 with a first depression 311 thereon and a second depression 312 thereunder, a crystal resonator 32 mounted on the first depression 311 by silver glues 33, and an application-specific integrated circuit chip (ASIC) 34 disposed on the second depression 312, and a cover 35 placed above the first depression 311. FIG. 1F further shows two of the crystal oscillator packages 30 mounted on a PCB P of a smartphone, each of which outputting a clock rate for operation.

The crystal oscillator package 20 and the crystal oscillator package 30 both are able to hold control of the phase noises and requires a fair area on a smartphone for installation; also, their integration function is satisfying. However, such structures require higher costs for parts in the manufacturing process.

FIG. 1G shows a conventional codec C used for audio system on smartphones mentioned on the official website of Xiaomi Inc. (http://www.mi.com/minote/hifi/). It consumes lower costs but functions poorly in the phase noise performance. Then there is a hi-fidelity (hi-fi) system F developed to present much lower noises for better audio quality of the music as shown in FIG. 1H, which was also mentioned on the website of Meizu Telecom Equipment Ltd (http://www.meizu.com/products/mx4pro/hifi.html). The hi-fi system F has two crystal oscillators 20, 30 combined with an isolated audio chip F1, an isolated amplifier F2, and other essential elements F3 to achieve the purpose of better audio quality for music with low phase noises from the two independent crystal oscillators 20, 30. Such structure has the installed PCB P setting up a CD sampling frequency as 44.1 kHz and a DVD sampling frequency as 48 kHz to process different audio formats. For further illustration, please see the chart below.

| | An audio format | |
|---|---|---|
| | multiplied by 44.1 kHz | An audio format multiplied by |
| | corresponding to one | 48 kHz corresponding to the |
| | of the crystal oscillators | other of the crystal oscillators |
| 512 times | 22.5792 MHz | 24.576 MHz |
| 1024 times | 45.1584 MHz | 49.152 MHz |
| 2048 times | 90.3168 MHz | 98.304 MHz |

From the chart we can learn that the frequencies multiplied by the sampling frequencies can also apply to the structures.

On the other hand, as shown in FIG. 11, the hi-fi system F requires two crystal oscillators; that is, the system needs connecting points for two isolated electricity power suppliers VDD, two ground connections GND, two signal input controllers INH, and two connecting points F out for frequency output. The input frequency of the system has to be switched between the signal input controllers INH for operation. In other words, such structure is not integrated.

FIG. 1J is disclosed in Japanese Patent No. 3770607. There is an integrated downsized crystal resonator package 40, including an insulating substrate 41 having an oblong depression 411, a first stair surface 412, and a second stair surface 413, a first electrode pad 42 disposed on the first and second stair surfaces 412, 413, a second electrode pad 43 disposed on the first and second stair surfaces 412, 413, a wiring conductor 44 arranged under the substrate 41 and electrically connected to the first and second electrode pads 42, 43, and a cover 45 disposed on the substrate 41. The crystal resonator package 40 thereby has a first crystal resonator 47A and a second crystal resonator 47B respectively mounted on the first and second electrode pads 42, 43 by a conductive adhesives 46. The package volume is therefore downsized.

FIG. 1L shows another downsized crystal resonator package 50 with airtight sealing disclosed in Japanese Patent No. 5882868. The package includes an insulating substrate 51 with a first depression 511 thereon connecting a second depression 512 thereunder via a through hole 513, a first wiring conductor 52 disposed in the first depression 511, a second wiring conductor 53 disposed in the second depression 512, a second crystal resonator 54B bonded to the second wiring conductor 53 by a bonding material 55, a second cover 56 sealing the second depression 512, a first crystal resonator 54A bonded to the first wiring conductor 52 by the bonding material 55, and a first cover 57 sealing the first depression 511. The first and second depressions 511, 512 are vacuumed via the through hole 513 to be airtight. The package volume is therefore downsized as well.

The package structures disclosed above mentioned nothing about hi-fi systems for musics. However, if they are applied to be mounted on a PCB for outputting different clock rates, there is still a problem of phase noises control.

All in all, the question is how to sustain a structure with two crystal oscillators that satisfies requirement of hi-fi system with low phase noises and meanwhile keeps the features of less volume and better integration; also, the costs for parts is another subject to be improved.

### SUMMARY OF THE INVENTION

A primary object of the present invention is to provide an integrated crystal oscillator package that holds control of phase noises to satisfy a hi-fi quality, keeps features of less area for installation of a circuit on smartphones and integration of different frequencies output from different clock rates, and reduces costs for parts in the manufacturing process.

To achieve the objects mentioned above, the present invention comprises a package including a substrate and cover, said substrate having a staircase depression with a first stair surface and a second stair surface, said first stair surface further having a first conductive section and said second stair surface further having a second conductive section, a third conductive section being arranged at a bottom of the staircase depression; a first quartz crystal resonator having an end thereof fixed on the first conductive section; a second quartz crystal resonator having an end thereof fixed on the second conductive section; and an application-specific integrated circuit chip (ASIC) combined on the third conductive section, said third conductive section further individually connected to the first and second conductive sections; whereby the ASIC has a switch control for operation when receiving audio formats with different degree of hi-fidelity (hi-fi) corresponding to a first clock rate output from the first quartz crystal resonator or to a second clock rate output from the second quartz crystal resonator.

Furthermore, frequencies of 44.1 kHz and a multiple thereof are corresponding to the first clock rate, and frequencies of 48 kHz and a multiple thereof are corresponding to the second clock rate. The first and second quartz crystal resonators have either the same sides or opposite sides fixed on the first and second conductive sections.

The substrate is a ceramic substrate or a PCB to have electric wires arranged therein separately connecting the third conductive section with the first and second conductive sections for the switch control to operate. The substrate further has a first bond pad group and a second bond pad group at a bottom thereof, said first and second bond pad groups individually coupled to the ASIC via the electric wires for the present invention to form a surface mount device (SMD).

The switch control has a first switch and a second switch to switch between a first sampling frequency output and a second sampling frequency output and to simultaneously output both frequencies.

With structures disclosed above, the present invention has the first quartz crystal resonator, the second quartz crystal resonator, and the ASIC combined in a package to form an integrated package structure that includes two isolated circuits and an isolated ASIC, so as to control the phase noises to achieve requirements of the hi-fi system and to ensure the package uses a minimum area on a smartphone with the feature of integration of different clock rates. In addition, the present invention consumes lower costs for parts in the manufacturing process.

### BRIEF DESCRIPTION OF THE DRAWINGS

FIG. 1A is a schematic diagram illustrating a structure of a conventional crystal resonator;

FIG. 1B is a schematic view of two conventional crystal resonators mounted on a PCB;

FIG. 1C is a schematic diagram illustrating a structure of a conventional crystal oscillator;

FIG. 1D is a schematic view of two conventional crystal oscillators mounted on a PCB;

FIG. 1E is a schematic diagram illustrating a structure of another conventional crystal oscillator;

FIG. 1F is a schematic view of two conventional crystal oscillators in FIG. 1E mounted on a PCB;

FIG. 1G is a schematic view of a conventional codec;

FIG. 1H is a schematic view of a conventional high-fidelity (hi-fi) system;

FIG. 1I is a schematic view of a conventional hi-fi system with a package of two crystal resonators;

FIG. 1J is a schematic diagram illustrating a structure of a downsized crystal resonator package according to the prior art;

FIG. 1K is a schematic diagram showing the downsized crystal resonator package mounted on a PCB;

FIG. 1L is a schematic diagram illustrating a structure of a downsized crystal resonator package with airtight sealing according to the prior art;

FIG. 1M is a schematic diagram showing the downsized crystal resonator package with airtight sealing mounted on a PCB;

FIG. 2 is a perspective view of the present invention;

FIG. 3 is a sectional view along line 3-3 in FIG. 2;

FIG. 4 is another sectional view of the present invention;

FIG. 5 is a schematic diagram illustrating the present invention mounted on a PCB;

FIG. 6A is a circuit diagram of the present invention; and

FIG. 6B is an application example of the present invention.

### DETAILED DESCRIPTION OF THE PREFERRED EMBODIMENT

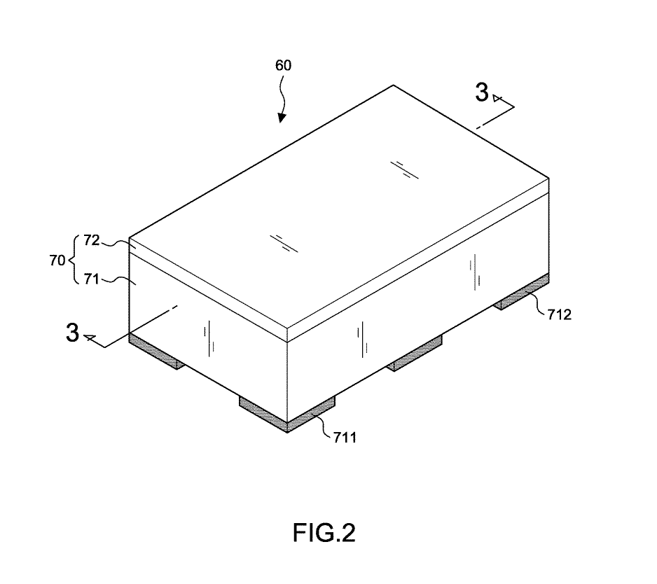

Referring to FIGS. 2-6B, in a preferred embodiment, an integrated crystal oscillator package 60 comprises a package 70, a first quartz crystal resonator 80A, a second quartz crystal resonator 80B, and an application-specific integrated circuit chip (ASIC) 90.

The package 70 includes a substrate 71 and cover 72. The substrate 71 has a staircase depression 73 with a first stair surface 74 and a second stair surface 75; the first stair surface 74 further has a first conductive section 741 and the second stair surface 75 further has a second conductive section 751, and a third conductive section 731 is arranged at a bottom of the staircase depression 73. In this embodiment, the substrate 71 is a ceramic substrate or a PCB to have electric wires (not shown) arranged therein, and the first, second, and third conductive sections 741, 751, 731 have a plurality of connecting points.

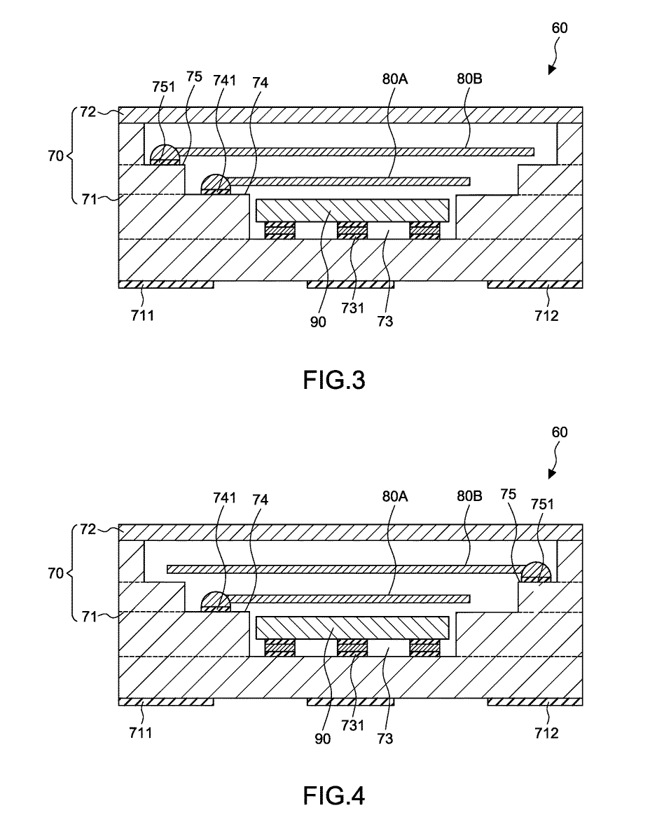

The first quartz crystal resonator 80A has an end thereof fixed on the first conductive section 741 on the first stair surface 74, and the second quartz crystal resonator 80B has an end thereof fixed on the second conductive section 751 on the second stair surface 75. Referring to FIGS. 3 and 4, in this embodiment the first and second quartz crystal resonators 80A, 80B may have their fixed ends either on the same sides or at opposite sides. Furthermore, the first and second quartz crystal resonators 80A, 80B are respectively coupled to the first and second conductive sections 741, 751 via the connecting points thereof, and the package 70 has the first and second quartz crystal resonators 80A, 80B airtight sealed therein.

The ASIC 90 is disposed on the third conductive section 731 of the staircase depression 73, and the third conductive section 731 is individually connected to the first conductive section 741 of the first stair surface 74 and the second conductive section 751 of the second stair surface 75. In this embodiment, the ASIC 90 is coupled to the connecting points of the third conductive section 731 and has the electric wires arranged therein to connect the third conductive section 731 with the first and second conductive sections 741, 751 for the ASIC 90 to be separately connected to the first quartz crystal resonator 80A and the second quartz crystal resonator 80B. In addition, the substrate 71 further has a first bond pad group 711 and a second bond pad group 712 at a bottom thereof, and the first and second bond pad groups 711, 712 are individually coupled to the ASIC 90 via the electric wires for the present invention to become a surface mount device (SMD).

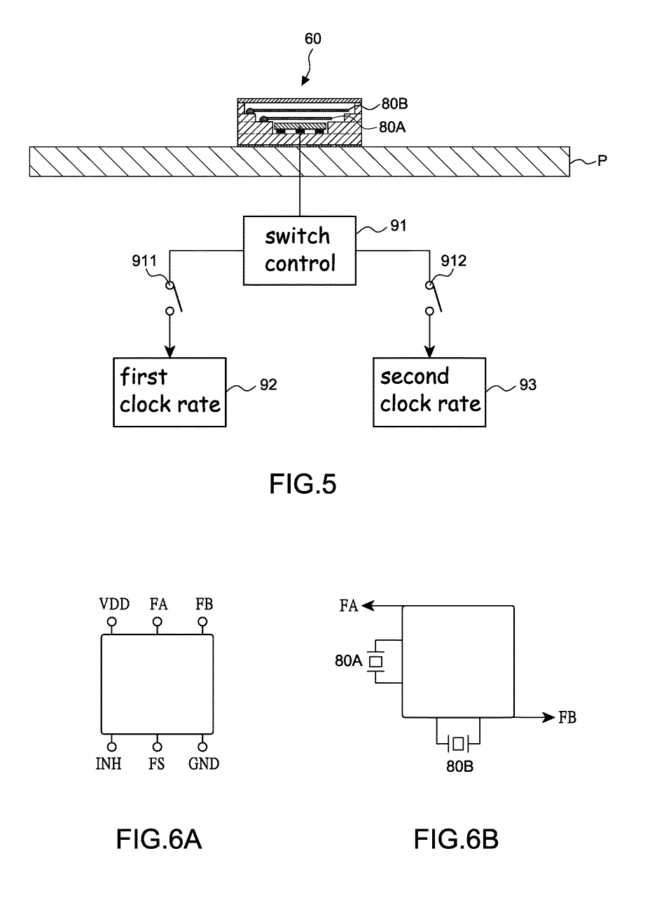

In FIG. 5, the integrated oscillator package 60 is mounted on a PCB P of a smartphone. In this application, the ASIC 90 has a switch control 91 to switch between different audio formats with different degree of hi-fidelity (hi-fi) to individually corresponds to a first clock rate 92 output from the first quartz crystal resonator 80A and to a second clock rate 93 output from the second quartz crystal resonator 80B, so as to form a structure of an integrated crystal oscillator package. In this embodiment, the switch control 91 has a first switch 911 and a second switch 912 to switch between the first clock rate 92 and the second clock rate 93 for output, or to simultaneously output both frequencies.

FIG. 6A illustrates a circuit diagram of the present invention. Normally a hi-fi system requires two crystal oscillators; in other words, there are isolated connecting points for two electricity power suppliers VDD, two ground connections GND, two signal input controllers INH, and two frequency outputs F. However, in the present invention the crystal oscillators are integrated into one single package which only requires connecting points for one electricity power supplier VDD, one ground connection GND, one signal input controller INH, one first clock rate output FA, one second clock rate output FB, and one switch transmission input FS. That is, the present invention is highly integrated to have two crystal oscillators and one ASIC within one package. In this embodiment, the audio formats are 44.1 kHz and 48 kHz. The first clock rate 92 outputs a 44.1 kHz frequency and the second clock rate 93 outputs a 48 kHz frequency. Further referring to FIG. 6B, the first and second crystal quartz resonators 80A, 80B can individually output the frequency or simultaneously output both frequencies in operation; the first clock rate 92 outputs a frequency of 44.1 kHz or a multiple thereof, and the second clock rate 93 outputs a frequency of 48 kHz or a multiple thereof.

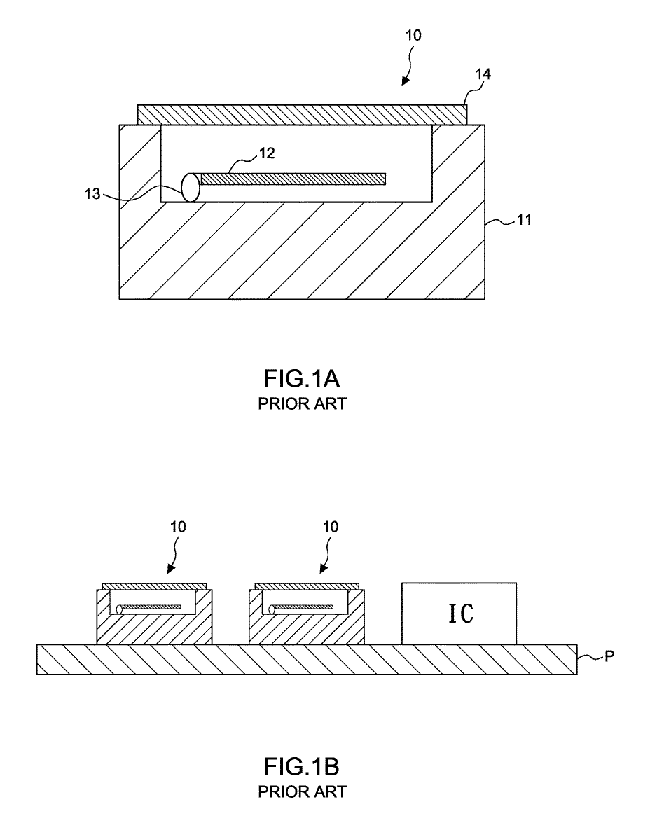

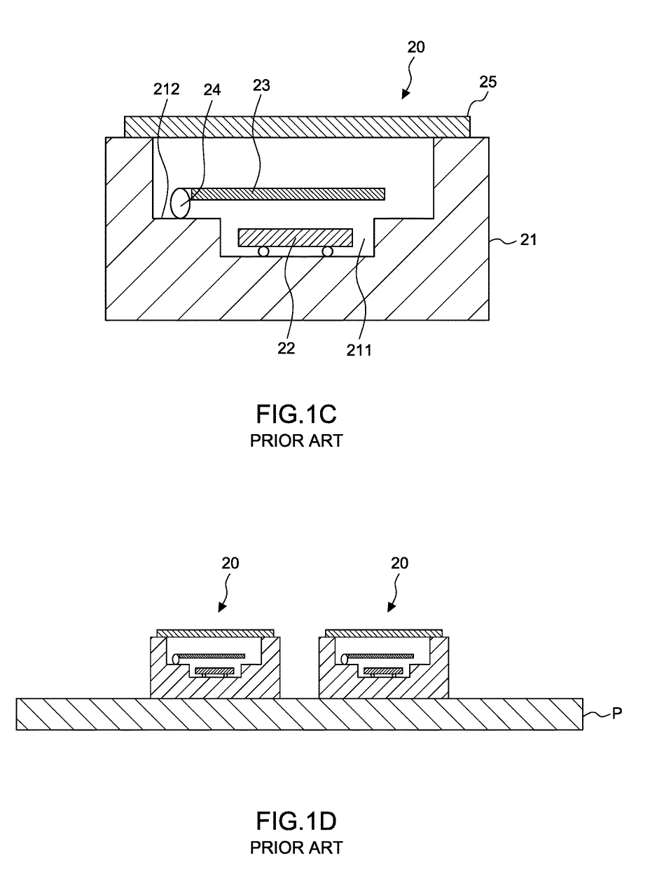

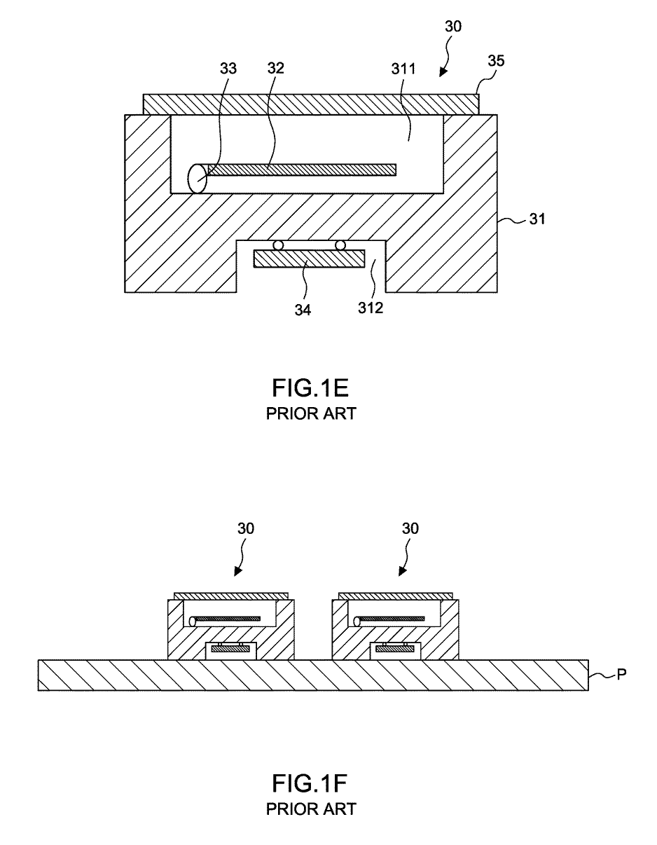

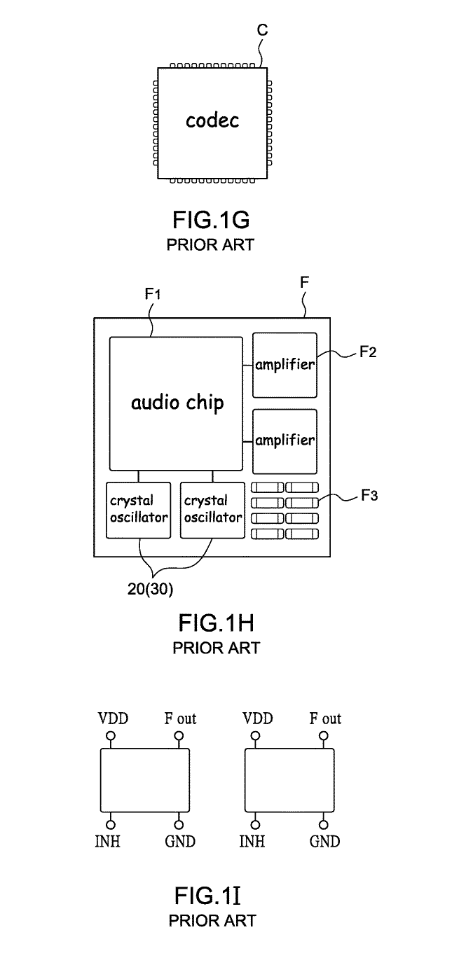

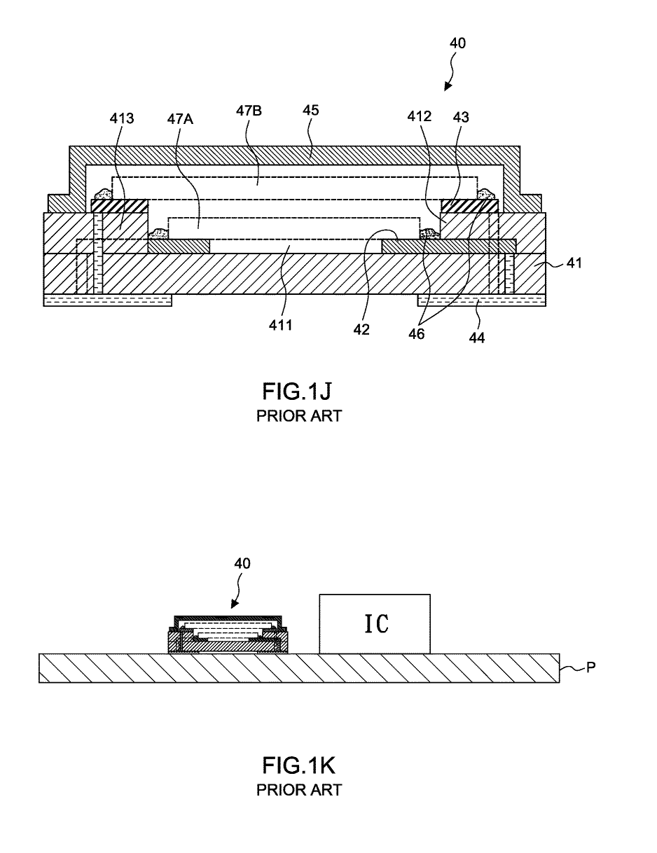

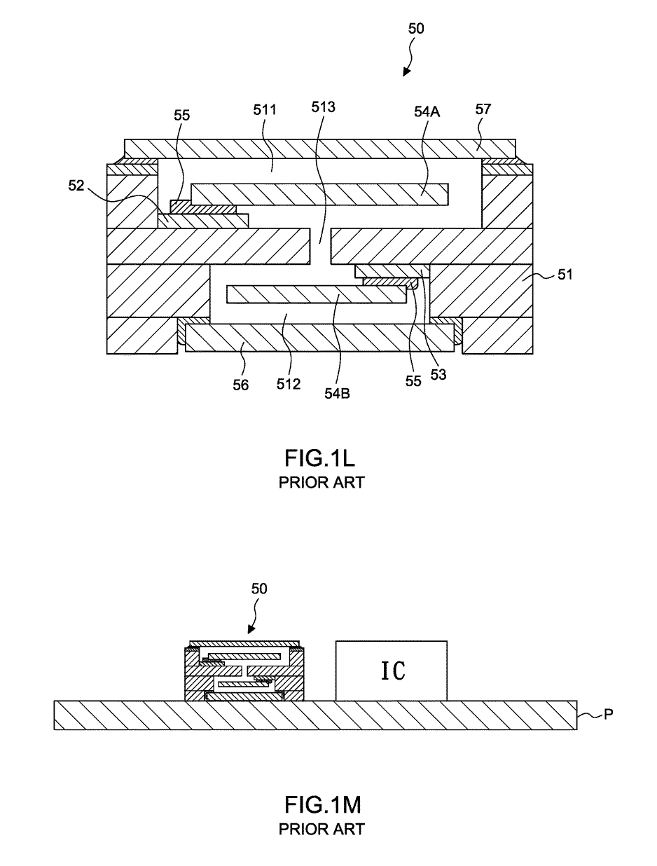

To further elaborate features of the present invention, please see the following chart for comparison.

| | Item | | | |
|---|---|---|---|---|
| | A | B | | |
| | Conventional | Conventional | C | D |
| | package | package | Conventional | Integrated |
| | structure of | structure of | integrated | package of |
| | two crystal | two crystal | package of two | crystal |
| | resonators | oscillators | crystal | oscillators |
| | (FIGS. | (FIGS. | resonators | (the present |
| | 1A-1B) | 1C-1F) | (FIGS. 1J-1M) | invention) |
| Quality | Excellent | Excellent | Excellent | Excellent |
| factor | | | | |
| Phase noise | Poor | Excellent | Poor | Excellent |
| control | | | | |
| Integration | Fair | Fair | Excellent | Excellent |
| of different | | | | |
| clock rates | | | | |
| Covering | Fair | Fair | Less | Less |
| area on a | | | | |
| smartphone | | | | |
| Costs for | Fair | High | Low | Fair |
| parts | | | | |

As the control of phase noises is a vital factor in hi-fi system, items A and C are ruled out undoubtedly. The present invention further integrates the crystal oscillators with an ASIC as a package to retain the features of excellent quality of phase noise control to satisfy the requirements of hi-fi systems and meanwhile keep the features of better integration and less covering area on a smartphone, therefore reducing the costs for parts as well.

In short, the present invention integrates the first and second crystal quartz resonators 80A, 80B and the ASIC 90, and keeps the feature of better phase noise control to achieve and satisfy the requirements of hi-fi systems; such structure also consumes lower costs for parts in the manufacturing process.

Although a particular embodiment of the invention has been described in detail for purposes of illustration, various modifications and enhancements may be made without departing from the spirit and scope of the invention. Accordingly, the invention is not to be limited except by the appended claims.

What is claimed is:

1. A structure of an integrated crystal oscillator package, comprising:
a package including a substrate and cover, said substrate having a staircase depression with a first stair surface and a second stair surface, said first stair surface further having a first conductive section and said second stair surface further having a second conductive section, a third conductive section being arranged at a bottom of the staircase depression;
a first quartz crystal resonator having an end thereof fixed on the first conductive section;
a second quartz crystal resonator having an end thereof fixed on the second conductive section; and
an application-specific integrated circuit chip (ASIC) combined on the third conductive section, said third conductive section further separately connected to the first and second conductive sections;
whereby the ASIC has a switch control to switch between audio formats with different degree of hi-fidelity (hi-fi) when receiving them and to operate correspondingly to a first clock rate output from the first quartz crystal resonator or to a second clock rate output from the second quartz crystal resonator.

2. The structure of an integrated crystal oscillator package as claimed in claim 1, wherein frequencies of 44.1 kHz and a multiple thereof are corresponding to the first clock rate, and frequencies of 48 kHz and a multiple thereof are corresponding to the second clock rate.

3. The structure of an integrated crystal oscillator package as claimed in claim 1, wherein the first and second quartz crystal resonators have either the same sides or opposite sides fixed on the first and second conductive sections.

4. The structure of an integrated crystal oscillator package as claimed in claim 1, wherein the substrate is a ceramic substrate or a PCB to have electric wires arranged therein separately connecting the third conductive section with the first and second conductive sections for the switch control to operate.

5. The structure of an integrated crystal oscillator package as claimed in claim 4, wherein the substrate further has a first bond pad group and a second bond pad group at a bottom thereof, said first and second bond pad groups individually coupled to the ASIC via the electric wires for the present invention to form a surface mount device (SMD).

6. The structure of an integrated crystal oscillator package as claimed in claim 1, wherein the switch control has a first switch and a second switch to switch between a first sampling frequency output and a second sampling frequency output and to simultaneously output both frequencies.

7. A structure of an integrated crystal oscillator package, comprising:
a package including a substrate and cover, said substrate having a staircase depression with a first stair surface and a second stair surface, said first stair surface further having a first conductive section and said second stair surface further having a second conductive section, a third conductive section being arranged at a bottom of the staircase depression;
a first quartz crystal resonator having an end thereof fixed on the first conductive section;
a second quartz crystal resonator having an end thereof fixed on the second conductive section; said end being at either the same side or an opposite side as the end of the first quartz crystal resonator fixed on the first conductive section; and
an application-specific integrated circuit chip (ASIC) combined on the third conductive section; the substrate being a ceramic substrate or a PCB to have electric wires arranged therein connecting the third conductive section with the first and second conductive sections individually for the switch control to operate, and the substrate further having a first bond pad group and a second bond pad group at a bottom thereof, said first and second bond pad groups individually coupled to the ASIC via the electric wires for the present invention to form a surface mount device (SMD);
whereby the ASIC has a switch control for operation when receiving audio format of 44.1 kHz and 48 kHz with different degree of hi-fidelity (hi-fi), the 44.1 kHz and a multiple thereof being corresponding to a first clock rate output from the first quartz crystal resonator and the 48 kHz and a multiple thereof being corresponding to a second clock rate output from the second quartz crystal resonator.

8. The structure of an integrated crystal oscillator package as claimed in claim 7, wherein the switch control has a first switch and a second switch to switch between a first sampling frequency output and a second sampling frequency output and to simultaneously output both frequencies.
